(19) United States
(12) Patent Application Publication
(10) Pub. No.: US 2016/0124542 A1
(43) Pub. Date: May 5, 2016

(54) CAPACITIVE TOUCH PANEL AND METHOD OF MAKING THE SAME

(71) Applicant: CANDO CORPORATION, Hsinchu (TW)

(72) Inventors: CHIH-TSUNG LEE, Nantou County (TW); YIH-JER LIN, Kaohsiung City (TW); CHI-KUANG LAI, Taoyuan County (TW); REN-YANG CHAO, Kaohsiung City (TW)

(21) Appl. No.: 14/711,474

(22) Filed: May 13, 2015

(30) Foreign Application Priority Data
Oct. 31, 2014 (TW) 103219366

(51) Int. Cl. G06F 3/044; C23C 14/34

(52) U.S. Cl. CPC G06F 3/044; C23C 14/34; G06F 2203/04103

(57) ABSTRACT

A capacitive touch panel and a method of making it are provided. The method first sputters a layer of TCO coatings on a transparent substrate to form a conductive portion and a base portion, and then coats a layer of transparent and insulating coatings on the conductive portion to form a blocking member. Another layer of TCO coatings is also sputtered on the conductive portion, the base portion, and the blocking member to form a first detection electrode assembly and a second detection electrode assembly. The first detection electrode assembly is arranged in a first axial direction with part thereof below the blocking member, while the second detection electrode assembly is arranged in a second axial direction, and part of the second detection electrode assembly covers the blocking member without contacting the first detection electrode assembly to make the first and the second detection electrode assemblies disconnect with each other.

### CROSS-REFERENCE TO RELATED APPLICATION

This application claims the priority benefit of Taiwan application serial No. 103219366, filed on Oct. 31, 2014. The entirety of the above-mentioned patent application is hereby incorporated by reference herein and made a part of this specification.

### BACKGROUND OF THE INVENTION

1. Technical Field

The present invention relates generally to a touch panel, and more particularly to a capacitive touch panel and a method of making the capacitive touch panel.

2. Description of Related Art

Touch screens are widely used as input interfaces of a variety of electronic devices in recent years, and the one glass solution (OGS) is becoming the main stream of the method of manufacturing touch panels in the industry.

The conventional manufacturing technique requires two separate pieces of glass, which are a touch sensor glass and a cover lens, to be joined together to form a single touch panel, while the OGS only needs, as implied in its name, one glass in the manufacturing process. Therefore, the OGS consumes less glass, and reduces manpower cost as well.

More specifically, the fundamental of the OGS is capacitance sensing. The manufacturing method includes coating photoresist or ink on the margin of a glass substrate to form a decorative layer first, and then sputtering transparent conductive oxide (TCO) thin films and metal wirings thereon to produce a detection portion which is capable of sensing touch coordinates. The conductive zone is composed of multiple detection electrode modules which establish an electric field on the surface. Touch motions can be detected by sensing electric capacitance change caused by the feeble current of human body.

The process of making the detection electrode modules used for the detection portion is shown in FIG. 1 to FIG. 6. The first step is providing a first bridge 91 in a first axial direction on a glass substrate 90, and then an insulating layer is plated thereon to cover part of the first bridge 91, wherein the uncovered part of the first bridge 91 forms two contact portions 91a at opposite ends, as shown in FIG. 3. After that, a second bridge 94 and four mutually separated TCO thin films 93, 95 are provided on the glass substrate 90, wherein the second bridge 94 is arranged in a second axial direction and on the insulating layer 92 without contacting the first bridge 91. The TCO thin films 93 are respectively connected to the contact portions 91a of the first bridge 91, while the TCO thin films 95 are connected to the second bridge 94. A detection electrode module is thus completed.

By installing multiple detection electrode modules on a panel, the detection portion of the touch panel is formed. For the aforementioned design, the resistance of the detection electrodes is a critical parameter. That is because most capacitive control chips process capacitive inductive signals by applying the charging method in a RC circuit, and therefore with higher total resistance of the TCO thin films, the charging time would be longer. In such cases, the touch panel may become less sensitive, or even have no response to touch motions.

In order to lower the total resistance, the electrode wiring has to be thickened since the size of each detection electrode in the detection portion is constant. However, to thicken the electrode wiring, the temperature during the sputtering process has to be increased, and therefore the thermotolerance of material of the insulating layer 92 should be taken into account. Thus, the electrode wiring can be only thickened to a certain extent. As a result, the total resistance cannot be further lowered.

In summary, it is difficult to lower the total resistance of the touch panel if the detection electrode modules are made with the aforementioned conventional method. The yield would be decreased, and the stability and lifespan of manufacturing equipment would be affected too.

### BRIEF SUMMARY OF THE INVENTION

In view of the above, the primary objective of the present invention is to provide a capacitive touch panel and a method of making the capacitive touch panel, which effectively lowers the total resistance of the touch panel without decreasing the yield or affecting the stability and lifespan of manufacturing equipment.

The present invention provides a capacitive touch panel, which includes a substrate, a first electrical connection layer, a blocking member, and a second electrical connection layer. The substrate is made of a transparent and insulating material. The first electrical connection layer is made of a transparent and conductive material, wherein the first electrical connection layer is provided on the substrate, and has a conductive portion and a base portion which are separated from each other. The blocking member is made of a transparent and insulating material, wherein part of the blocking member covers the conductive portion of the first electrical connection layer. The second electrical connection layer has two first electrode plates and a second electrode plate which are separated from each other, wherein at least one electrode plate among the first electrode plates and the second electrode plate is provided on the base portion; the first electrode plates are arranged in a first axial direction, and connected to two ends of the conductive portion of the first electrical connection layer to form a first detection electrode assembly; the second electrode plate is arranged in a second axial direction, which is different from the first axial direction, to form a second detection electrode assembly; part of the second electrode plate covers the blocking member without contacting the conductive portion of the first electrical connection layer, which makes the first detection electrode assembly and the second detection electrode assembly disconnect with each other.

According to an embodiment of the present invention, the second electrical connection layer covers larger area than the first electrical connection layer, and part of the second electrical connection layer covers the first electrical connection layer and the blocking member, while a rest part of the second electrical connection layer directly covers the substrate.

According to an embodiment of the present invention, part of the first electrode plate which does not cover the base portion of the first electrical connection layer is connected to the two ends of the conductive portion.

The present invention further provides another capacitive touch panel, which includes a substrate, a first detection electrode assembly, a blocking member, and a second detection electrode assembly. The substrate is made of a transparent and insulating material. The first detection electrode assembly is made of a transparent and conductive material, and is provided on the substrate in a first axial direction. The blocking member is made of a transparent and insulating material, and is provided on the first detection electrode assembly. The second detection electrode assembly is made of a transparent and conductive material, and is provided on the substrate in a second axial direction which is different from the first axial direction; part of the second detection electrode assembly covers the blocking member without contacting the first detection electrode assembly, which makes the first detection electrode assembly and the second detection electrode assembly disconnect with each other; a thickness of the second detection electrode assembly above the blocking member is less than that of other parts of the second detection electrode assembly, and also less than a thickness of the first detection electrode assembly

The present invention also provides a method of making a capacitive touch panel, which includes the following steps: A. sputter a layer of transparent and conductive coatings on a transparent substrate to form a conductive portion and a base portion on the substrate; B. coat transparent and insulating coatings on the conductive portion to form a blocking member thereon; and C. sputter another layer of transparent and conductive coatings on the conductive portion, the base portion and the blocking member to form a first detection electrode assembly and a second detection electrode assembly on the substrate, wherein the first detection electrode assembly is arranged in a first axial direction with part thereof located under the blocking member, while the second detection electrode assembly is arranged in a second axial direction, which is different from the first axial direction; part of the second detection electrode assembly covers the blocking member without contacting the first detection electrode assembly, which makes the first detection electrode assembly and the second detection electrode assembly disconnect to each other.

Whereby, with the aforementioned method of multi-layer stacking, the transparent electrode can be thickened without deteriorating the insulating material, for the manufacturing process does not require an excessively high temperature. As a result, the yield can be increased, and the stability and lifespan of manufacturing equipment can be improved as well.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a top view of the glass substrate of a conventional manufacturing process, showing the first bridge is provided thereon;

FIG. 2 is a sectional view along the A-A line in FIG. 1;

FIG. 3 is a top view of the glass substrate of the conventional manufacturing process, showing the insulating layer is provided on the first bridge;

FIG. 4 is a sectional view along the B-B line in FIG. 3;

FIG. 5 is a top view of the detection electrode module made by the conventional manufacturing process;

FIG. 6 is a sectional view along the C-C line in FIG. 5;

FIG. 7 is a schematic diagram of a first preferred embodiment of the present invention, showing a first electrical connection layer provided one a substrate;

FIG. 8 is a sectional view along the D-D line in FIG. 7;

FIG. 9 is a schematic diagram of the first preferred embodiment of the present invention, showing a blocking member provided on a conductive portion of the first electrical connection layer;

FIG. 10 is a sectional view along the E-E line in FIG. 9;

FIG. 11 is a top view of the first preferred embodiment of the present invention;

FIG. 12 is a sectional view along the F-F line in FIG. 11; and

FIG. 13 is a sectional view of a second preferred embodiment of the present invention.

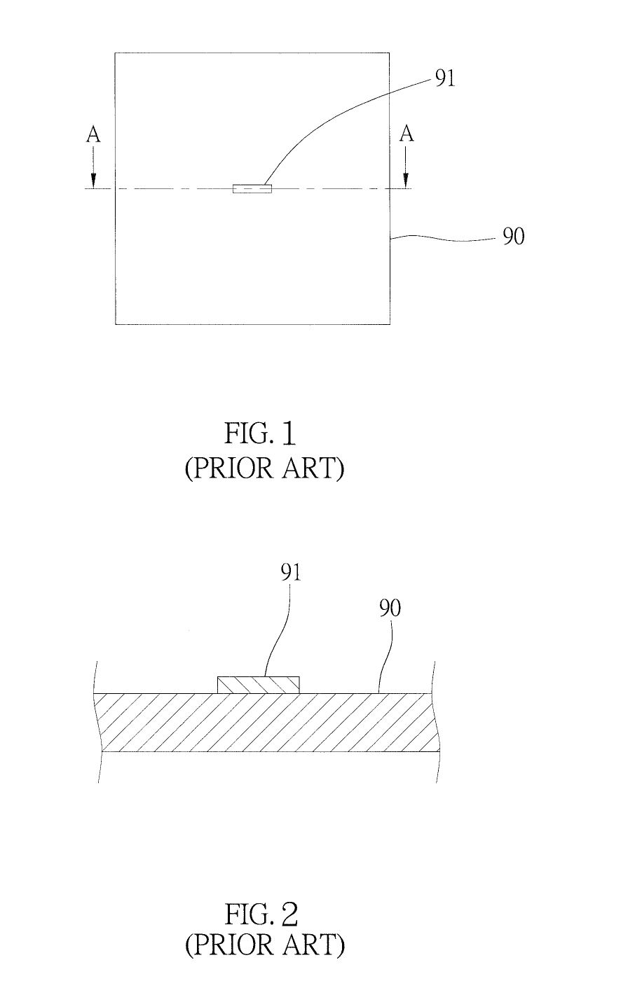

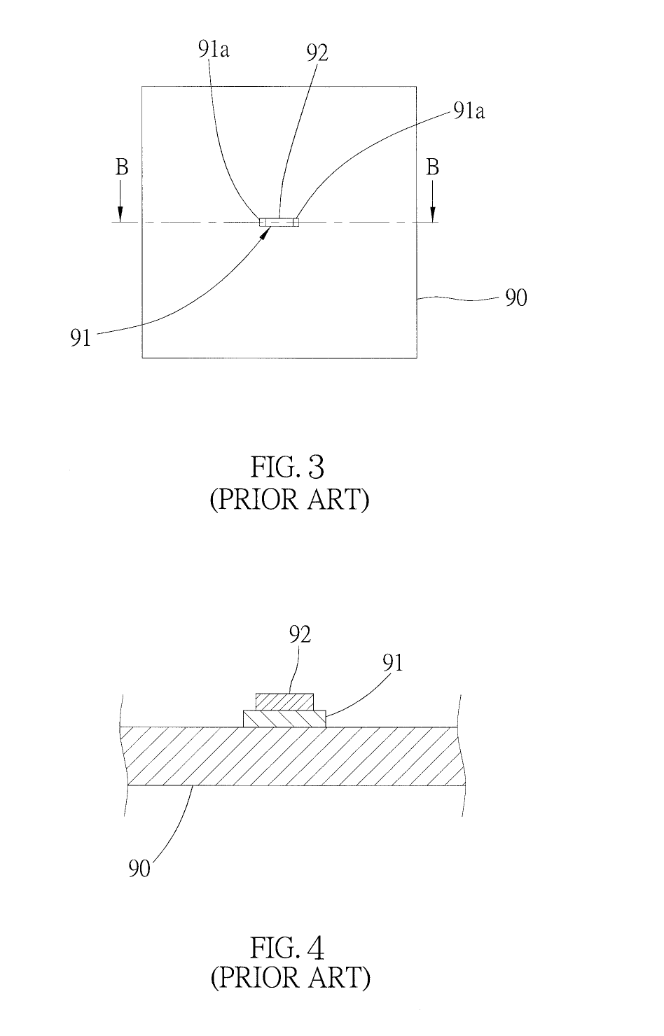

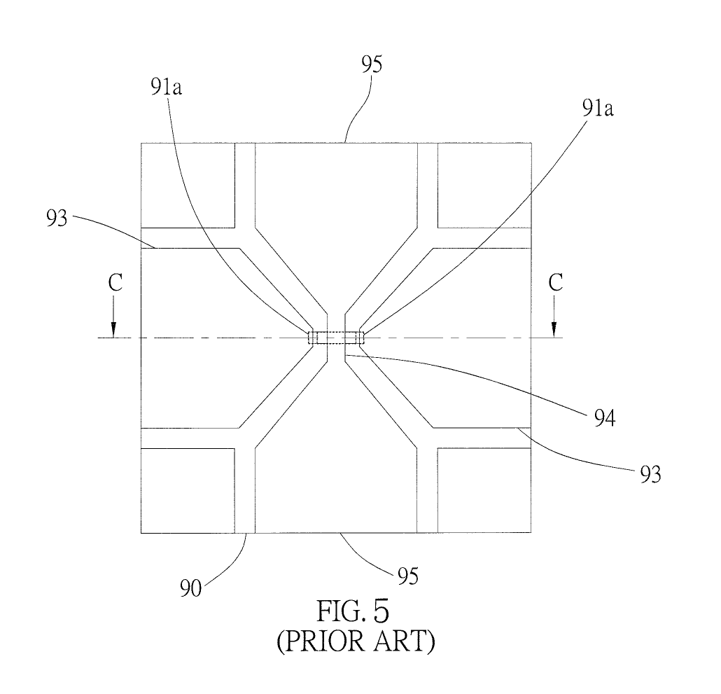

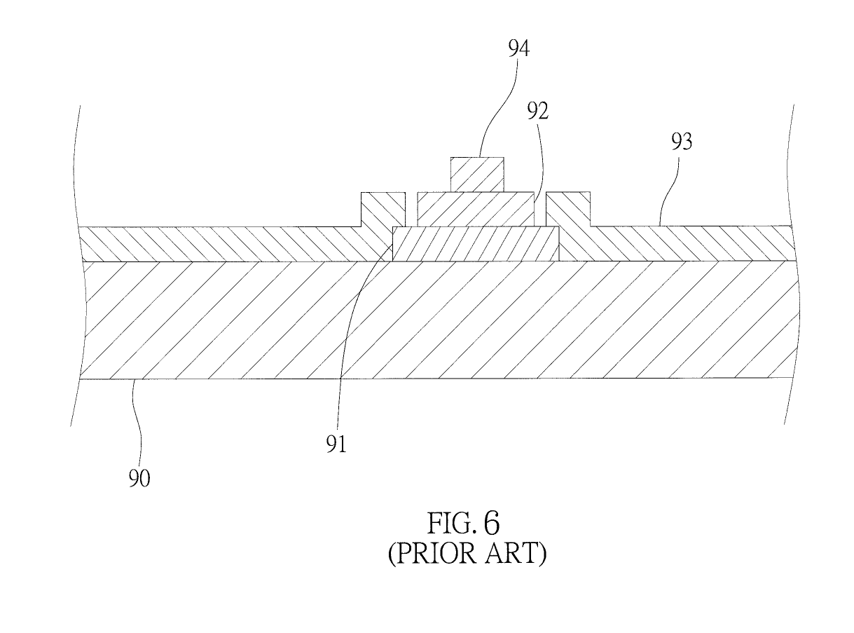

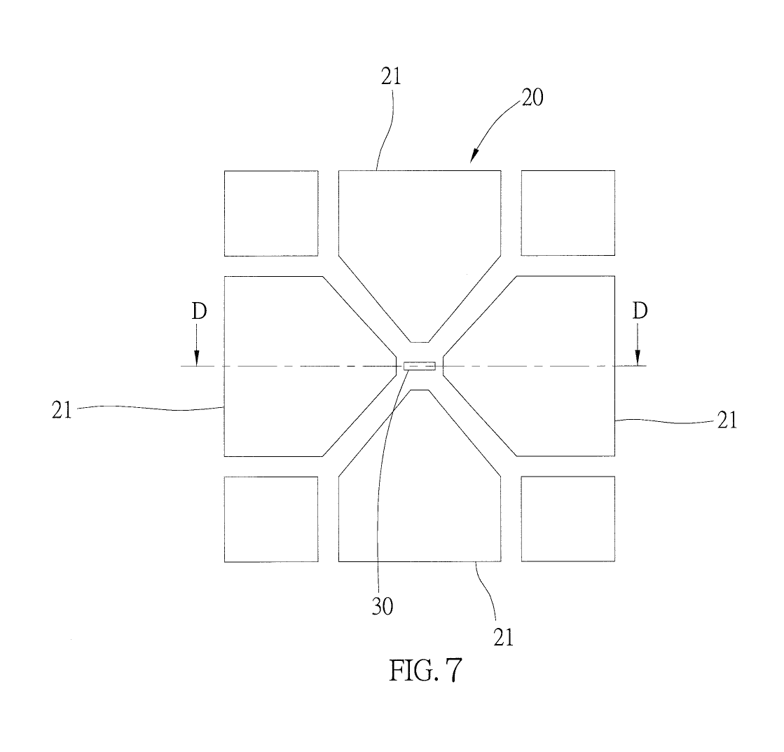

### DETAILED DESCRIPTION OF THE INVENTION

As shown in FIG. 7 to FIG. 12, a method of making a capacitive touch panel 100 of the first preferred embodiment of the present invention mainly includes the following steps:

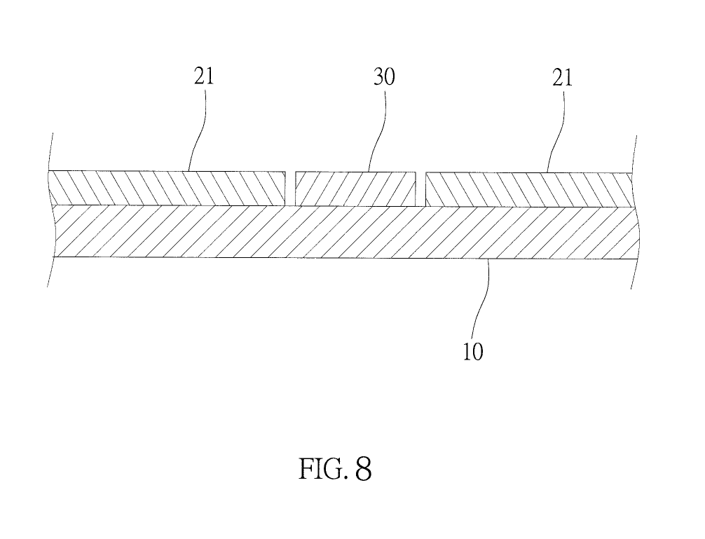

In the first step, which is shown in FIG. 7 and FIG. 8, TCO (Transparent Conductive Oxide) coatings are sputtered on a transparent substrate 10 made of glass or plastic, and a plurality of first electrical connection layers 20, each of which has a certain pattern, are formed on the substrate 10 by photolithography etching.

More specifically, the TCO coatings are Indium TinOxide (ITO) in the first preferred embodiment of the present invention; as in other embodiments, the TCO coatings can also be selected from ZnO:Al (AZO), ZnO:Ga (GZO), SnO₂:F (FTO), PEDOT, carbon nano tube (CNT), metallic silver nanowire, Mg(OH)₂:C, grapheme, and other transparent and conductive materials.

In addition, in the first preferred embodiment of the present invention, each of the first electrical connection layers 20 includes a base portion, which is composed of a plurality of sensing units 21, and a conductive portion 30. For convenience of explanation, each of the first electrical connection layers 20 in the first preferred embodiment of the present invention has two sensing units 21 arranged in a first axial direction, and another two sensing units 21 arranged in a second axial direction. However, this is not a limitation of the present invention. People who have ordinary skill in the art would know the number of the sensing units may vary depending on different requirements. In the first preferred embodiment of the present invention, the first axial direction is a lateral direction, while the second axial direction is longitudinal and perpendicular to the first axial direction. The conductive portion 30 is located between the sensing units 21, and at where the first axial direction and the second axial direction intersect without contacting the sensing units 21. In the first preferred embodiment of the present invention, the conductive portion 30 is a long rectangle with its long side parallel to the first axial direction and short side parallel to the second axial direction. The shape of the conductive portion 302 is not a limitation of the present invention either. In practice, it can be a further elongated rectangle, an ellipse, or other required shape.

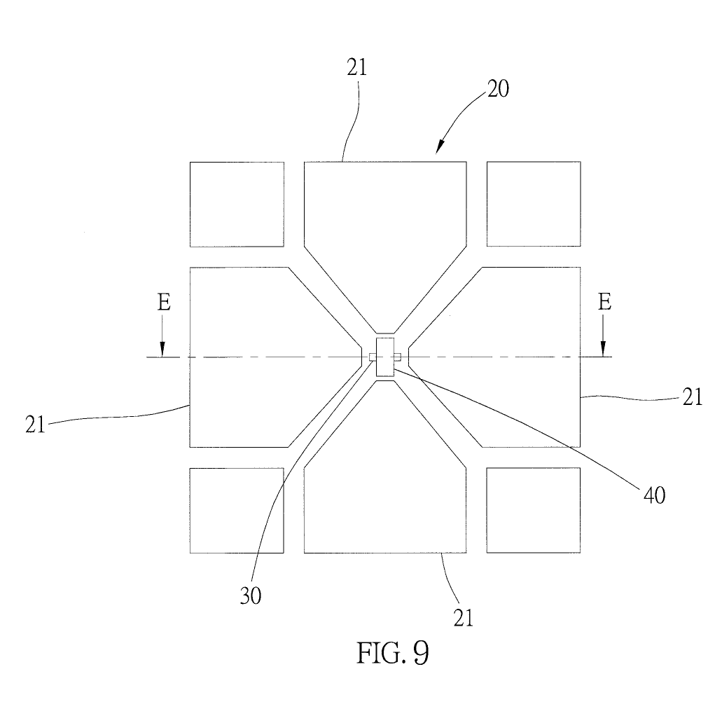

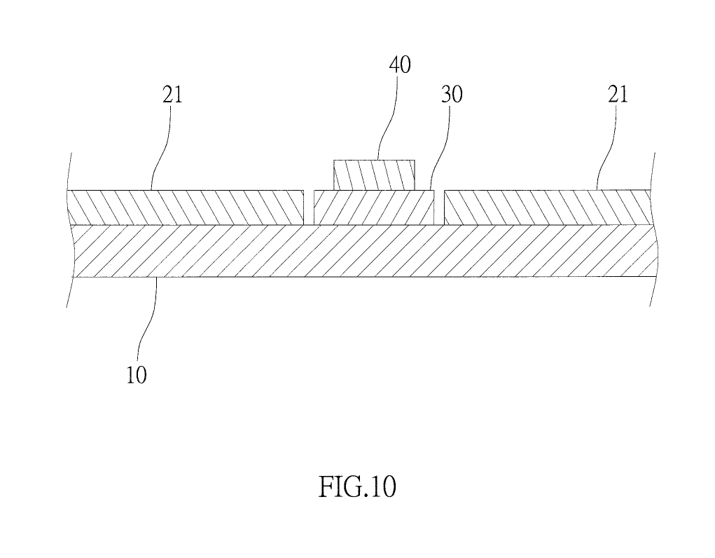

After completing the first step to form the multiple first electrical connection layers 20 on the substrate 10, in the second step as shown in FIG. 9 and FIG. 10, a layer of transparent and insulating coatings is coated on each of the conductive portions 30 to cover part of the conductive portion 30 and form a blocking member 40 as an insulating bridge, which prevents the conductive portion 30 thereunder from upwardly conducting other components. The uncovered part of the conductive portion 30 forms two opposite exposed ends. In the first preferred embodiment, the transparent and insulating coatings are made of Polymide (PI). However, this is not a limitation of the present invention, and in other embodiments, the coatings can be also selected from Polyethylene terephthalate (PET), Polymethylmethacrylate (PMMA), or other transparent and insulating materials.

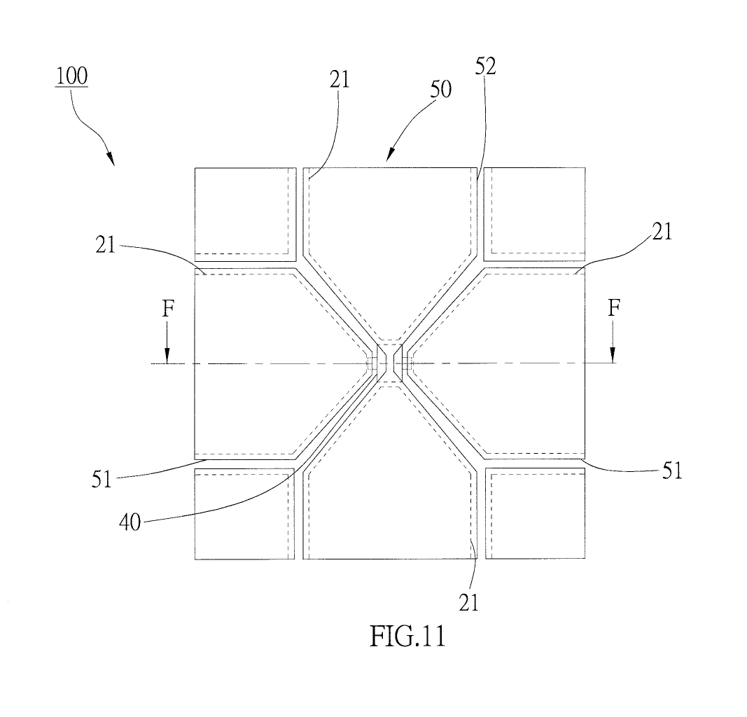

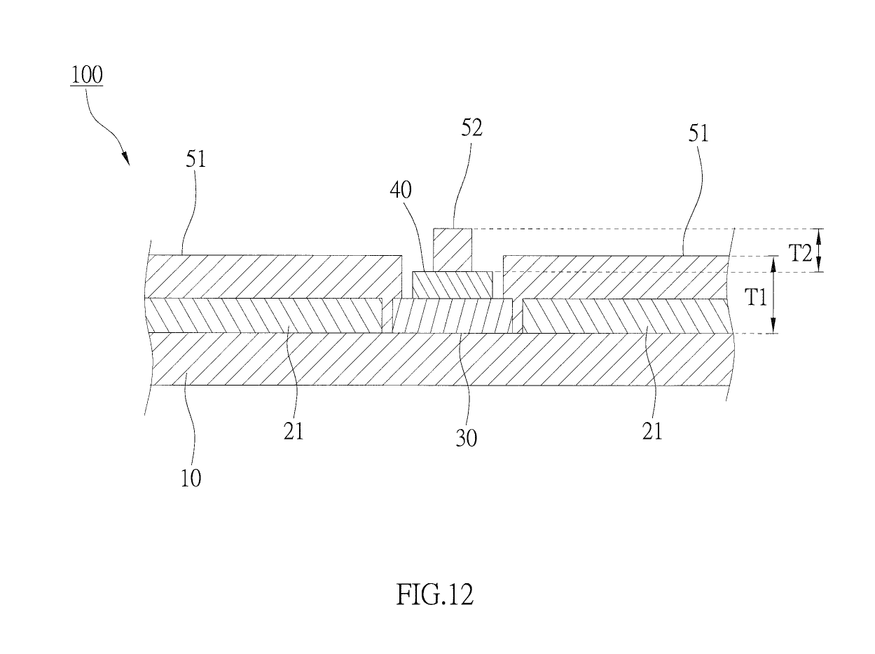

After completing the second step to form the blocking member 40 on the conductive portion 30, in the third step as shown in FIG. 11 and FIG. 12, another layer of transparent and conductive coatings are further sputtered on the substrate 10, the sensing units 21, the conductive portion 30, and the blocking member 40. Similarly, a second electrical connection layer 50, each of which has a certain pattern, are formed on the sensing units 21, the conductive portion 30, and the blocking member 40 by photolithography etching.

It is worth mentioning that, the transparent and conductive coatings used in the third step is the same with the TCO coatings used in the first step. However, other materials can be used too. The concentration of the coatings will affect the resulting thickness, and therefore the concentration should be adjusted according to different requirement. Furthermore, the second electrical connection layer 50 covers larger area than the first electrical connection layer 50, and therefore part of the second electrical connection layer 50 covers the sensing units 21, the conductive portion 30, and the blocking member 40, while the rest part thereof directly covers the substrate 10.

In addition, each of the second electrical connection layers 50 in the preferred embodiment of the present invention includes two first electrode plates 51 and a second electrode plate 52 which are mutually separated, wherein the first electrode plates 51 respectively cover the sensing units 21 arranged in the first axial direction, and part of the first electrode plates 51 which does not cover the sensing unit 21 is connected to the ends of the conductive portion 30 of the first electrical connection layer 20. In this way, a plurality of first detection electrode assemblies is formed on the substrate 10 to constitute a conductive path in the first axial direction. As for the second electrode plate 52, it covers the blocking member 40 and the sensing units 21 arranged in the second axial direction to form a plurality of second detection electrode assemblies on the substrate 10, and a conductive path in the second axial direction is constituted as a result.

It is worth mentioning that, by using the aforementioned method of multi-layer stacking to form the first detection electrode assemblies and the second detection electrode assemblies, a thickness T2 of each of the second detection electrode assemblies above the corresponding blocking member 40 is less than that of other parts of the second detection electrode assembly, and also less than a thickness T1 of each of the first detection electrode assemblies. In addition, since part of the second electrode plate 52 is above the blocking member 40 without contacting the conductive portion 30 of the first electrical connection layer 20, the second detection electrode assemblies and the first detection electrode assemblies are disconnected to each other, and therefore these two units do not interfere with each other.

With the aforementioned method of multi-layer stacking of the TCO coatings, the detection electrode assemblies are effectively thickened, which further decreases a total resistance of the capacitive touch panel. Moreover, since each layer of the TCO coatings is thin, the process of sputtering the conductive coatings does not need higher temperature, which effectively prevents the insulating materials from deteriorating due to high temperature. In other words, the aforementioned method not only effectively lowers the total resistance, but also increases the yield, improves the stability during the manufacturing process, and extends the lifespan of manufacturing equipment.

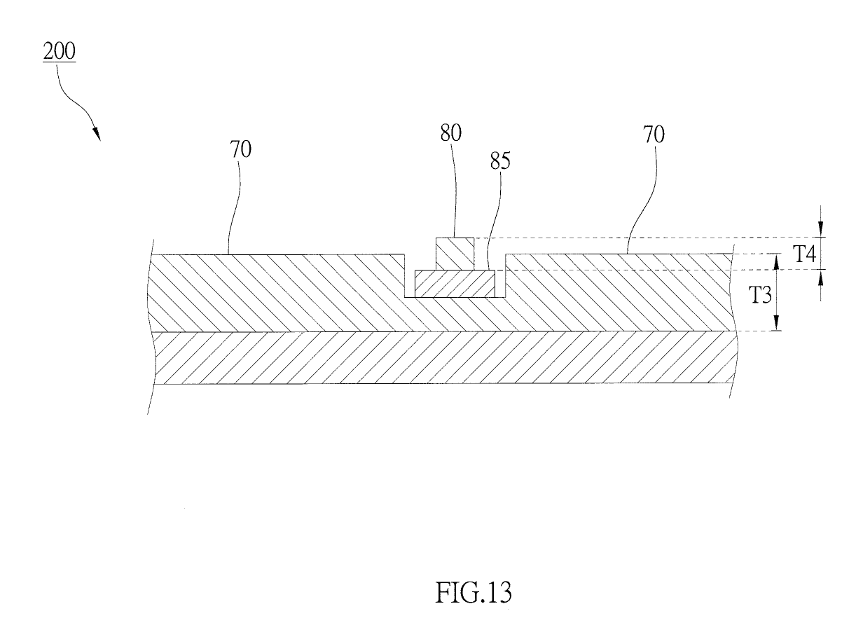

In addition, as shown in FIG. 13, a capacitive touch panel 200 of the second preferred embodiment of the present invention differs from the capacitive touch panel 100 of the first preferred embodiment, where the concentration of the TCO coatings for each sputtering is the same, or at least approximately the same, and the working temperature is the same or similar, too. As a result, the detection electrode assemblies 70 of the capacitive touch panel 200 are not layered as the first preferred embodiment. However, since the capacitive touch panel 200 is still made by the aforementioned method of multi-layer stacking, a thickness T3 of one of the detection electrode assemblies 70 is still larger than a thickness T4 of another detection electrode assembly above the blocking member 85. Thus, the second preferred embodiment of the present invention also has the aforementioned advantages of lowering the total resistance, improving the yield, increasing the stability during the manufacturing process, and extending the lifespan of manufacturing equipment can be achieved.

It is worth mentioning that, in practice, the first electrode plates 51 and the second electrode plate 52 are not necessary to have similar shape with the sensing units 21. For different requirements, the sensing units 21, the first electrode plates 51, and the second electrode plate 52 can also have quite different shapes. In other embodiments, the sensing units 21 can be only formed in either the first axial direction or the second axial direction, and only the first electrode plates 51 or the second electrode plate 52 in the same direction is sputtered on the sensing unit 21; the rest parts are directly sputtered on the substrate. Therefore, the second detection electrode assembly and the first detection electrode assembly may have different thickness, and the resistance can be adjusted in this way.

In summary, the capacitive touch panel and the method of making the capacitive touch panel provided in the present invention not only provides a way to thicken each of the electrodes by sputtering the TCO coatings for several times, but also allows a manufacturer to adjust the concentration and the thickness of the conductive coatings used to form electrodes in order to make touch panels with different resistances.

It must be pointed out that the embodiments described above are only some preferred embodiments of the present invention. Though only two-layered stacking is introduced above, stacking of more layers is, of course, also possible in practice. All equivalent structures and methods which employ the concepts disclosed in this specification and the appended claims should fall within the scope of the present invention.

What is claimed is:

1. A capacitive touch panel, comprising:
a substrate made of a transparent and insulating material;
a first electrical connection layer made of a transparent and conductive material, wherein the first electrical connection layer is provided on the substrate, and has a conductive portion and a base portion which are separated from each other;
a blocking member made of a transparent and insulating material, wherein part of the blocking member covers the conductive portion of the first electrical connection layer; and
a second electrical connection layer having two first electrode plates and a second electrode plate which are separated from each other, wherein at least one electrode plate among the first electrode plates and the second electrode plate is provided on the base portion; the first electrode plates are arranged in a first axial direction, and connected to two ends of the conductive portion of the first electrical connection layer to form a first detection electrode assembly; the second electrode plate is arranged in a second axial direction, which is different from the first axial direction, to form a second detection electrode assembly; part of the second electrode plate covers the blocking member without contacting the conductive portion of the first electrical connection layer, which makes the first detection electrode assembly and the second detection electrode assembly disconnect with each other.

2. The capacitive touch panel of claim 1, wherein the second electrical connection layer covers larger area than the first electrical connection layer, and part of the second electrical connection layer covers the first electrical connection layer and the blocking member, while a rest part of the second electrical connection layer directly covers the substrate.

3. The capacitive touch panel of claim 2, wherein part of the first electrode plate which does not cover the base portion of the first electrical connection layer is connected to the two ends of the conductive portion.

4. The capacitive touch panel of claim 1, wherein the base portion includes a plurality of separated sensing units; the conductive portion is located between the sensing units.

5. The capacitive touch panel of claim 4, wherein the sensing units are arranged in the first axial direction; the first electrode plate is provided on the sensing units, while the second electrode plate is provided on the substrate.

6. The capacitive touch panel of claim 4, wherein the sensing units are arranged in the second axial direction; the second electrode plate is provided on the sensing units, while the first electrode plates are provided on the substrate.

7. The capacitive touch panel of claim 4, wherein the first electrode plates and the second electrode plate are respectively provided on the sensing units.

8. The capacitive touch panel of claim 1, wherein the conductive portion of the first electrical connection layer and the blocking member are located at where the first axial direction and the second axial direction intersect.

9. A capacitive touch panel, comprising:
a substrate made of a transparent and insulating material;
a first detection electrode assembly made of a transparent and conductive material, wherein the first detection electrode assembly is provided on the substrate in a first axial direction;
a blocking member made of a transparent and insulating material, wherein the blocking member is provided on the first detection electrode assembly; and
a second detection electrode assembly made of a transparent and conductive material, wherein the second detection electrode assembly is provided on the substrate in a second axial direction which is different from the first axial direction; part of the second detection electrode assembly covers the blocking member without contacting the first detection electrode assembly, which makes the first detection electrode assembly and the second detection electrode assembly disconnect with each other; a thickness of the second detection electrode assembly above the blocking member is less than that of other parts of the second detection electrode assembly, and also less than a thickness of the first detection electrode assembly.

10. The capacitive touch panel of claim 9, wherein a thickest thickness of the first detection electrode assembly is not equal to a thickest thickness of the second detection electrode assembly.

11. The capacitive touch panel of claim 9, wherein the blocking member is located at where the first axial direction and the second axial direction intersect.

12. The capacitive touch panel of claim 9, wherein the first axial direction is perpendicular to the second axial direction.

13. A method of making a capacitive touch panel, comprising the steps of:
A. sputtering a layer of transparent and conductive coatings on a transparent substrate to form a conductive portion and a base portion on the substrate;
B. coating transparent and insulating coatings on the conductive portion to form a blocking member thereon; and
C. sputtering another layer of transparent and conductive coatings on the conductive portion, the base portion and the blocking member to form a first detection electrode assembly and a second detection electrode assembly on the substrate, wherein the first detection electrode assembly is arranged in a first axial direction with part thereof located under the blocking member, while the second detection electrode assembly is arranged in a second axial direction, which is different from the first axial direction; part of the second detection electrode assembly covers the blocking member without contacting the first detection electrode assembly, which makes the first detection electrode assembly and the second detection electrode assembly disconnect to each other.

14. The method of claim 13, wherein the base portion includes a plurality of sensing units which are separated from each other; the conductive portion is located between the sensing units.

15. The method of claim 14, wherein the sensing units are arranged in either the first axial direction or the second axial direction.

16. The method of claim 15, wherein a thickness of the first detection electrode assembly is not equal to a thickness of the second detection electrode assembly.

17. The method of claim 14, wherein a part of the sensing units is arranged in the first axial direction, while another part of the sensing units is arranged in the second axial direction.

18. The method of claim 13, wherein the coatings used in step A covers less area than the coatings used in step C, which makes part of the coatings used in step C covers the conductive portion and the base portion, and a rest part of the coatings used in step C directly covers the substrate.

19. The method of claim 13, wherein a thickness of the second detection electrode assembly above the blocking member is less than that of other parts of the second detection electrode assembly, and also less than a thickness of the first detection electrode assembly.

20. The method of claim 13, wherein the coatings used in step C forms two first electrode plates and a second electrode plate on the conductive portion, the base portion, and the blocking member; at least one electrode plate among the first electrode plates and the second electrode plate is provided on the base portion; the first electrode plates are arranged in the first axial direction, and respectively connected to two ends of the conductive portion to form the first detection electrode assembly; the second electrode plate is arranged in the second axial direction with part thereof covers the blocking member to form the second detection electrode assembly.
